(19) United States
(12) Patent Application Publication
(10) Pub. No.: US 2017/0327630 A1
(43) Pub. Date: Nov. 16, 2017

(54) RESIN FILM, COVERLAY FOR PRINTED WIRING BOARD, SUBSTRATE FOR PRINTED WIRING BOARD, AND PRINTED WIRING BOARD

(71) Applicant: SUMITOMO ELECTRIC PRINTED CIRCUITS, INC., Koka-shi, Shiga (JP)

(72) Inventors: Satoshi KIYA, Koka-shi (JP); Sumito UEHARA, Koka-shi (JP); Kousuke MIURA, Koka-shi (JP)

(73) Assignee: SUMITOMO ELECTRIC PRINTED CIRCUITS, INC., Koka-shi, Shiga (JP)

(21) Appl. No.: 15/520,135

(22) PCT Filed: Oct. 13, 2015
(86) PCT No.: PCT/JP2015/078903

§ 371 Date: Apr. 19, 2017

(30) Foreign Application Priority Data
Oct. 21, 2014 (JP) 2014-214814

(51) Int. Cl. C08G 59/30; H05K 3/26; H05K 3/12; C08J 7/16; B32B 27/38; H05K 3/38; B32B 27/30

(52) U.S. Cl. CPC C08G 59/30; H05K 3/38; H05K 3/26; B32B 27/30; C08J 7/16; B32B 27/38; H05K 3/1208

(57) ABSTRACT

A resin film containing a fluororesin as a main component has, on at least one surface thereof, a pre-treated surface having a content ratio of oxygen atoms or nitrogen atoms of 0.2 atomic percent or more. A coverlay includes the resin film and an adhesive layer laminated on the pre-treated surface. A substrate for a printed wiring board includes the resin film and a conductive layer laminated on the pre-treated surface. A printed wiring board includes an insulating base layer, a conductive pattern laminated on at least one surface of the base layer, and the coverlay for a printed wiring board, the coverlay being laminated on the conductive pattern.

### TECHNICAL FIELD

The present invention relates to a resin film, a coverlay for a printed wiring board, a substrate for a printed wiring board, and a printed wiring board.

### BACKGROUND ART

In printed wiring boards, resin films having insulating properties are used as, for example, a base layer that supports a conductive pattern and a coverlay that protects a conductive pattern. When high-frequency signals are treated with such a printed wiring board, transmission loss characteristics of the high-frequency signals may be significantly affected by the dielectric constant of, for example, a resin film near a conductive pattern. In order to reduce transmission loss, resin films preferably have low dielectric constants. In view of this, it has been proposed that low-dielectric constant materials such as fluororesins are used as materials of base layers of printed wiring boards for high-frequency applications (refer to, for example, Japanese Unexamined Patent Application Publication No. 2013-165171).

### CITATION LIST

### Patent Literature

PTL 1: Japanese Unexamined Patent Application Publication No. 2013-165171

### SUMMARY OF INVENTION

### Technical Problem

Since fluororesins have low adhesiveness, for example, as described in the above patent application publication, an existing fluororesin film used as a base layer for a printed wiring board is formed as a porous body, and pores of the porous body are filled with a material constituting a conductive layer or another layer or a material having a high affinity with a conductive layer or another layer, thereby ensuring an adhesive force between the fluororesin film and the other layer.

However, in addition to a high cost of a porous material, it is necessary to impregnate pores of the porous material with a material, and thus it may not be easy to laminate another material on the porous material. Accordingly, when an existing fluororesin film is used as a base layer or a coverlay of a printed wiring board, it may not be easy to laminate another layer (for example, a coverlay with respect to a base layer) or layers of the resulting laminate may be easily separated from each other.

The present invention has been made in view of the circumstances described above. An object of the present invention is to provide a resin film which has a low dielectric constant and on which another material can be easily and reliably laminated, a coverlay for a printed wiring board, the coverlay being easily laminated on a printed wiring board and being unlikely to separate from the printed wiring board, and a substrate for a printed wiring board and a printed wiring board on which a coverlay or the like can be easily laminated and from which the laminated layer is unlikely to separate.

### Solution to Problem

A resin film according to an embodiment of the present invention, which has been made to solve the problems described above, is a resin film containing a fluororesin as a main component. The resin film has, on at least one surface thereof, a pre-treated surface having a content ratio of oxygen atoms or nitrogen atoms of 0.2 atomic percent or more.

### Advantageous Effects of Invention

The resin film according to an embodiment of the present invention has a low dielectric constant, and another material can be easily and reliably laminated on the resin film.

### BRIEF DESCRIPTION OF DRAWINGS

FIG. 1 is a schematic sectional view illustrating a printed wiring board according to an embodiment of the present invention.

FIG. 2A is a schematic sectional view illustrating a step of producing a coverlay of the printed wiring board in FIG. 1.

FIG. 2B is a schematic sectional view illustrating a step of producing a coverlay of the printed wiring board in FIG. 1, the step being performed subsequent to the step illustrated in FIG. 2A.

FIG. 2C is a schematic sectional view illustrating a state of a coverlay of the printed wiring board in FIG. 1 before being bonded to a wiring substrate.

FIG. 3A is a schematic sectional view illustrating a step of producing a wiring substrate of the printed wiring board in FIG. 1.

FIG. 3B is a schematic sectional view illustrating a step of producing a wiring substrate of the printed wiring board in FIG. 1, the step being performed subsequent to the step illustrated in FIG. 3A.

FIG. 3C is a schematic sectional view illustrating a step of producing a wiring substrate of the printed wiring board in FIG. 1, the step being performed subsequent to the step illustrated in FIG. 3B.

FIG. 3D is a schematic sectional view illustrating a step of producing a wiring substrate of the printed wiring board in FIG. 1, the step being performed subsequent to the step illustrated in FIG. 3C.

FIG. 3E is a schematic sectional view illustrating a step of producing a wiring substrate of the printed wiring board in FIG. 1, the step being performed subsequent to the step illustrated in FIG. 3D.

FIG. 3F is a schematic sectional view illustrating a state of a wiring substrate of the printed wiring board in FIG. 1 before being bonded to a coverlay.

### DESCRIPTION OF EMBODIMENTS

### Description of Embodiments of the Present Invention

A resin film according to an embodiment of the present invention is a resin film containing a fluororesin as a main component. The resin film has, on at least one surface thereof, a pre-treated surface having a content ratio of oxygen atoms or nitrogen atoms of 0.2 atomic percent or more.

The resin film contains a fluororesin as a main component and thus has a low dielectric constant. Furthermore, since the resin film has a pre-treated surface having a content ratio of oxygen atoms or nitrogen atoms of 0.2 atomic percent or more, hydrophobicity of the fluororesin is reduced by these atoms, and adhesiveness is improved. Accordingly, another material can be easily and reliably laminated on the resin film.

A contact angle of the pre-treated surface with respect to pure water is preferably 90° or less. When the contact angle of the pre-treated surface with respect to pure water is 90° or less, the resin film has higher adhesiveness to another material.

A peel strength of an epoxy resin adhesive having an average thickness of 25 μm to the pre-treated surface, the peel strength being measured using a polyimide sheet having an average thickness of 12.5 μm as a flexible adherend, is preferably 1 N/cm or more. When the peel strength of an epoxy resin adhesive having an average thickness of 25 μm to the pre-treated surface is equal to or more than the lower limit, separation of a bonded object laminated on the resin film can be suppressed.

A coverlay for a printed wiring board according to an embodiment of the present invention includes the resin film and an adhesive layer laminated on the pre-treated surface.

According to the coverlay for a printed wiring board, a printed wiring board can be easily bonded to the pre-treated surface of the resin film. In addition, since an adhesive layer having a high adhesive strength with the resin film is laminated, lamination of the coverlay on a printed wiring board is further facilitated, and the resin film is unlikely to separate.

A peel strength between the adhesive layer and the pre-treated surface is preferably 1 N/cm or more. At a peel strength between the adhesive layer and the pre-treated surface of 1 N/cm or more, the resin film is unlikely to separate when the coverlay is bonded to a printed wiring board.

A substrate for a printed wiring board according to an embodiment of the present invention is a substrate for a printed wiring board, the substrate including the resin film and a conductive layer laminated on the pre-treated surface.

According to the substrate for a printed wiring board, since a conductive layer is laminated on the pre-treated surface, the conductive layer is unlikely to separate from the resin film, and reliability can be improved.

A peel strength between the pre-treated surface and the conductive layer is preferably 1 N/cm or more. When the peel strength between the pre-treated surface and the conductive layer is 1 N/cm or more, reliability can be further improved.

A printed wiring board according to an embodiment of the present invention includes an insulating base layer, a conductive pattern laminated on at least one surface of the base layer, and the coverlay for a printed wiring board, the coverlay being laminated on the conductive pattern.

Since the printed wiring board includes the coverlay for a printed wiring board, lamination of the coverlay in the production step can be easily performed, and the laminated coverlay is unlikely to separate.

A printed wiring board according to another embodiment of the present invention includes the resin film, and a conductive pattern laminated on the pre-treated surface.

According to the printed wiring board, since a conductive pattern is laminated on the pre-treated surface, lamination of the conductive pattern in the production step can be easily performed, and the conductive pattern is unlikely to separate.

A printed wiring board according to still another embodiment of the present invention includes the resin film, and a conductive pattern laminated on a surface of the resin film, in which the pre-treated surface is disposed in a conductive pattern-non-laminated region on the surface of the resin film.

According to the printed wiring board, since the pre-treated surface is disposed in a conductive pattern-non-laminated region of the resin film, adhesiveness of the resin film in the conductive pattern-non-laminated region to a coverlay or the like is improved. Therefore, according to the printed wiring board, a coverlay or the like can be easily laminated in the conductive pattern-non-laminated region, and the laminated coverlay or the like is unlikely to separate.

Herein, the term “main component” refers to a component having a higher content than other components and refers to a component contained in an amount of preferably 50% by mass or more. The “content ratio of oxygen atoms or nitrogen atoms” can be measured by, for example, electron spectroscopy for chemical analysis (ESCA) or X-ray photoelectron spectroscopy (XPS), energy-dispersive X-ray spectroscopy (EDX) or energy-dispersive X-ray spectroscopy (EDS), electron probe micro-analysis (EPMA), time-of-flight secondary ion mass spectrometry (TOF-SIMS), secondary ion mass spectrometry (SIMS), Auger electron spectroscopy (AES), or electron microscopy. In the case of ESCA or XPS, the measurement can be performed by scanning a surface under the measurement conditions of an X-ray source of a K-alpha line of aluminum metal, a beam diameter of 50 and an X-ray incident angle of 45° with respect to the analysis surface. A Quantera instrument manufactured by ULVAC-Phi, Incorporated can be used as the apparatus. In the case where a measurement surface is not exposed, the material is sequentially removed by sputtering in a direction perpendicular to the measurement surface, and the composition ratio of atoms at a position at any depth can be thereby determined by any of the above methods. Even on a cross section perpendicular to a measurement surface, the content ratio of oxygen atoms or nitrogen atoms on the surface can be measured by performing evaluation using the above methods in combination. For example, the thickness of a surface-treated layer may be measured with an electron microscope while the impurity concentration is analyzed in the depth direction by, for example, SIMS while removing the material by sputtering in a direction substantially parallel to the measurement surface. The term “contact angle with respect to pure water” refers to a value of a contact angle measured by the sessile drop method in accordance with JIS-R-3257 (1999). The contact angle can be measured by using, for example, a contact angle meter “G-I-1000” available from ERMA Inc. The term “peel strength of an epoxy resin adhesive having an average thickness of 25 μm to the pre-treated surface, the peel strength being measured using a polyimide sheet having an average thickness of 12.5 μm as a flexible adherend” refers to a value measured by the method in accordance with JIS-K-6854-2 (1999) “Adhesives-Determination of peel strength of bonded assemblies-Part 2: 180° peel”. In the measurement of the peel strength, a coverlay formed of a laminate including a polyimide sheet and an epoxy adhesive is used. Among coverlays “CM-type” manufactured by Arisawa Manufacturing Co., Ltd., a coverlay including “Apical NPI” manufactured by Kaneka Corporation as a polyimide sheet is used as the coverlay. The term “peel strength between an adhesive layer and a pre-treated surface” refers to a value measured by the method in accordance with JIS-K-6854-2 (1999) “Adhesives-Determination of peel strength of bonded assemblies-Part 2: 180° peel” using a sample prepared by bonding a coverlay for a printed wiring board to a polyimide sheet having an average thickness of 12.5 μm and serving as a flexible adherend. In the measurement of the peel strength, “Apical NPI” manufactured by Kaneka Corporation is used as the polyimide sheet. If the resin film has an insufficient rigidity, the measurement may be performed in a state in which a reinforcing material is laminated on a surface on the opposite side of the pre-treated surface. The term “peel strength between a pre-treated surface and a conductive layer” refers to a value measured by the method in accordance with JIS-K-6854-2 (1999) “Adhesives-Determination of peel strength of bonded assemblies-Part 2: 180° peel” using the resin film as a flexible adherend. If the conductive layer has an insufficient rigidity, the measurement may be performed in a state in which a reinforcing material is laminated on a surface on the opposite side of the resin film.

### Details of Embodiments of the Present Invention

A printed wiring board according to an embodiment of the present invention will now be described in detail with reference to the drawings.

### [Printed Wiring Board]

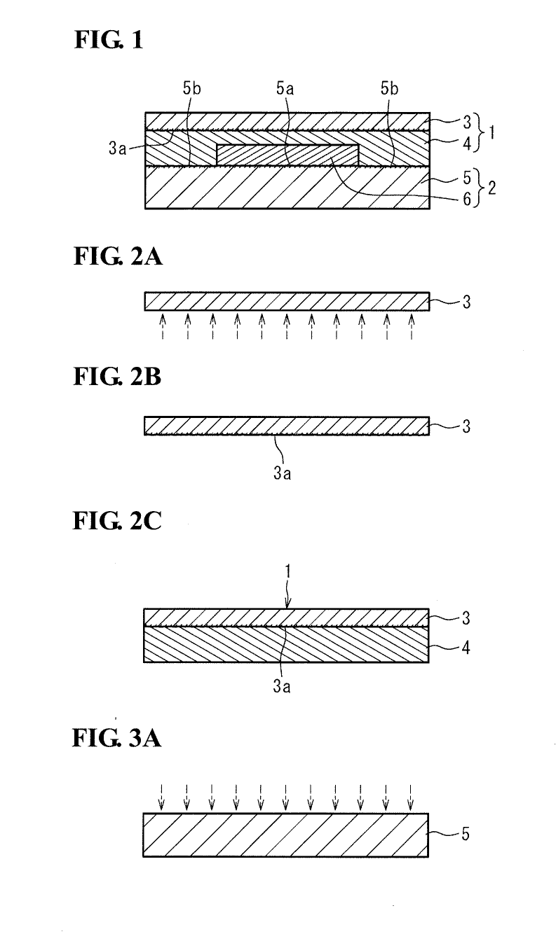

A printed wiring board illustrated in FIG. 1 includes a coverlay 1 and a wiring substrate 2 on which the coverlay 1 is laminated on a front surface side. The coverlay 1 is an embodiment of the present invention. The wiring substrate 2 is an embodiment of a printed wiring board according to the present invention. Herein, in the printed wiring board, the side on which the coverlay 1 is laminated is defined as “front” and the opposite side thereof is defined as “back”.

### <Coverlay>

The coverlay 1 includes a resin film 3 containing a fluororesin as a main component and an adhesive layer 4 laminated on a back surface (on the lower side in the figure) of the resin film 3. The resin film 3 of the coverlay 1 is an embodiment of the present invention.

### (Resin Film)

The resin film 3 has, on a surface on which the adhesive layer 4 is laminated, a pre-treated surface 3a having a content ratio of oxygen atoms or nitrogen atoms of 0.2 atomic percent or more. In other words, the pre-treated surface 3a is a surface having an atomic composition different from the inside of the resin film 3.

Examples of the fluororesin serving as the main component of the resin film 3 include polytetrafluoroethylene (PTFE), polytetrafluoroethylene-perfluoroalkyl vinyl ether copolymers (PFA), tetrafluoroethylene-hexafluoropropylene copolymers (FEP), ethylene-tetrafluoroethylene copolymers (ETFE), polyvinylidene fluoride (PVDF), polychlorotrifluoroethylene (PCTFE), ethylene-chlorotrifluoroethylene copolymers (ECTFE), polyvinyl fluoride (PVF), and thermoplastic fluororesins (THV) and fluoroelastomers obtained from three monomers of tetrafluoroethylene, hexafluoropropylene, and vinylidene fluoride. Mixtures and copolymers containing these compounds can also be used as the main component of the resin film 3.

Among these, a tetrafluoroethylene-hexafluoropropylene copolymer (FEP), a polytetrafluoroethylene-perfluoroalkyl vinyl ether copolymer (PFA), or polytetrafluoroethylene (PTFE) is preferred as the fluororesin serving as the main component of the resin film 3. Use of any of these fluororesins as the main component provides the resin film 3 with flexibility, optical transparency, heat resistance, and flame retardancy.

The resin film 3 may contain, as optional components, for example, an engineering plastic, a flame retardant, a flame retardant assistant, a pigment, an antioxidant, a reflection-imparting agent, a masking agent, a lubricant, a processing stabilizer, a plasticizer, a foaming agent, and a reinforcing material.

The engineering plastic may be selected from publicly known engineering plastics in accordance with properties required for the resin film 3 and used. Typically, an aromatic polyether ketone can be used.

This aromatic polyether ketone is a thermoplastic resin having a structure in which benzene rings are bonded in the para-position and the benzene rings are connected together through a rigid ketone bond (—C(═O)—) or a flexible ether bond (—O—). Examples of the aromatic polyether ketone include ether ether ketones (PEEK) having a structural unit in which an ether bond, a benzene ring, an ether bond, a benzene ring, a ketone bond, and a benzene ring are arranged in that order and polyether ketones (PEK) having a structural unit in which an ether bond, a benzene ring, a ketone bond, and a benzene ring are arranged in that order. Among these, PEEK is preferred as the aromatic polyether ketone. Such aromatic polyether ketones have, for example, good wear resistance, heat resistance, insulating properties, and processability.

Commercially available aromatic polyether ketones may be used as the aromatic polyether ketones such as PEEK. Various grades of aromatic polyether ketones are commercially available. A single grade of a commercially available aromatic polyether ketone may be used alone. Alternatively, a plurality of grades of commercially available aromatic polyether ketones may be used in combination. Modified aromatic polyether ketones may also be used.

The lower limit of a ratio of the total content of the engineering plastic to the fluororesin in the resin film 3 is not particularly limited, but is preferably 10% by mass, more preferably 20% by mass, and still more preferably 35% by mass. The upper limit of the ratio of the total content of the engineering plastic to the fluororesin is not particularly limited, but is preferably 50% by mass, and more preferably 45% by mass. When the total content of the engineering plastic is less than the lower limit, properties of the resin film 3 may not be sufficiently improved. When the total content of the engineering plastic exceeds the upper limit, advantageous properties of the fluororesin may not be sufficiently exhibited.

Various publicly known flame retardants can be used as the flame retardant. Examples thereof include halogen-based flame retardants such as bromine-based flame retardants and chlorine-based flame retardants.

Various publicly known flame retardant assistants can be used as the flame retardant assistant. An example thereof is antimony trioxide.

Various publicly known pigments can be used as the pigment. An example thereof is titanium oxide.

Various publicly known antioxidants can be used as the antioxidant. Examples thereof include phenol-based antioxidants.

Various publicly known reflection-imparting agents can be used as the reflection-imparting agent. An example thereof is a titanium oxide.

Examples of the reinforcing material include carbon fibers, glass fibers, aramid fibers, alumina fibers, and liquid-crystal polymer (LCP) fibers. Threads or cloths formed of any of these fibers, for example, a glass cloth may be used.

The lower limit of the average thickness of the resin film 3 of the coverlay 1 is preferably 5 μm, and more preferably 10 μm. The upper limit of the average thickness of the resin film 3 is preferably 250 μm, and more preferably 125 μm. When the average thickness of the resin film 3 is less than the lower limit, the coverlay 1 may have insufficient strength. When the average thickness of the resin film 3 exceeds the upper limit, the coverlay 1, and furthermore, the printed wiring board may have insufficient flexibility.

### <Pre-Treated Surface>

The pre-treated surface 3a is formed by a surface treatment on the back surface of the resin film 3 and contains oxygen atoms or nitrogen atoms.

The lower limit of the content ratio of oxygen atoms or nitrogen atoms of the pre-treated surface 3a is 0.2 atomic percent, preferably 1 atomic percent, and more preferably 5 atomic percent. The upper limit of the content ratio of oxygen atoms or nitrogen atoms of the pre-treated surface 3a is preferably 30 atomic percent, and more preferably 20 atomic percent. When the content ratio of oxygen atoms or nitrogen atoms of the pre-treated surface 3a is less than the lower limit, adhesiveness between the resin film 3 and the adhesive layer 4 may be insufficient. When the content ratio of oxygen atoms or nitrogen atoms of the pre-treated surface 3a exceeds the upper limit, oxygen atoms or nitrogen atoms are excessively contained, and thus the skeleton may be broken and resin film 3 may have insufficient strength. Either the content ratio of oxygen atoms or the content ratio of nitrogen atoms of the pre-treated surface 3a may be the lower limit or more. However, preferably, each of the content ratio of oxygen atoms and the content ratio of nitrogen atoms is the lower limit or more.

The upper limit of the contact angle of the pre-treated surface 3a with respect to pure water is preferably 90°, and more preferably 80°. The lower limit of the contact angle of the pre-treated surface 3a with respect to pure water is not particularly limited. When the contact angle of the pre-treated surface 3a with respect to pure water exceeds the upper limit, adhesive strength between the resin film 3 and the adhesive layer 4 may be insufficient.

The lower limit of the peel strength of an epoxy resin adhesive having an average thickness of 25 μm to the pre-treated surface 3a, the peel strength being measured using a polyimide sheet having an average thickness of 12.5 μm as a flexible adherend, is preferably 1 N/cm, and more preferably 5 N/cm. When the peel strength of the epoxy resin adhesive to the pre-treated surface 3a is less than the lower limit, the adhesive strength between the resin film 3 and the adhesive layer 4 may be insufficient.

The lower limit of a wetting tension of the pre-treated surface 3a is preferably 50 mN/m, and more preferably 60 mN/m. When the wetting tension of the pre-treated surface 3a is less than the lower limit, an adhesive force between the resin film 3 and the adhesive layer 4 may be insufficient, and the adhesive layer 4 may be separated.

### (Adhesive Layer)

The adhesive layer 4 is formed of an adhesive laminated on the pre-treated surface 3a of the resin film 3.

Examples of a main component of the adhesive that forms the adhesive layer 4 include polyimides, epoxy resins, polystyrene, alkyd resins, urethane resins, phenolic resins, melamine resins, acrylic resins, polyamides, polyethylene, polypropylene, polyesters, vinyl acetate resins, and rubbers. The coverlay 1 can be easily bonded to the wiring substrate 2 by using, as the adhesive layer 4, a pressure sensitive adhesive containing an acrylic resin, a silicone resin, a urethane resin, or the like as the main component.

The lower limit of the average thickness of the adhesive layer 4 is preferably 5 μm, and more preferably 10 μm.

The upper limit of the average thickness of the adhesive layer 4 is preferably 100 μm, and more preferably 50 μm. When the average thickness of the adhesive layer 4 is less than the lower limit, the adhesive strength of the adhesive layer 4 to the resin film 3 may be insufficient. When the average thickness of the adhesive layer 4 exceeds the upper limit, the coverlay 1, and furthermore, the printed wiring board may have an unnecessarily large thickness.

The lower limit of the peel strength between the adhesive layer 4 and the pre-treated surface 3a is preferably 1 N/cm, and more preferably 5 N/cm. When the peel strength between the adhesive layer 4 and the pre-treated surface 3a is less than the lower limit, only the resin film 3 may be separated from the coverlay 1 bonded to the printed wiring board.

### <Wiring Substrate>

The wiring substrate 2 includes a resin film 5 containing a fluororesin as a main component and serving as an insulating base layer, and a conductive pattern 6 laminated on a front surface (surface on the upper side in the figure) of the resin film 5. The resin film 5 of the wiring substrate 2 is an embodiment of the present invention.

### (Resin Film)

The resin film 5 has a first pre-treated surface 5a having a content ratio of oxygen atoms or nitrogen atoms of 0.2 atomic percent or more and disposed in a region where the conductive pattern 6 is laminated, the region being disposed on a surface on which the conductive pattern 6 is to be laminated, and a second pre-treated surface 5b having a content ratio of oxygen atoms or nitrogen atoms of 0.2 atomic percent or more and disposed in a region where the conductive pattern is not laminated, the region being disposed on the surface on which the conductive pattern 6 is to be laminated.

The material of the resin film 5 of the wiring substrate 2 may be the same as the material of the resin film 3 of the coverlay 1.

The lower limit of the average thickness of the resin film 5 is preferably 5 μm, and more preferably 10 μm. The upper limit of the average thickness of the resin film 5 is preferably 100 μm, and more preferably 50 μm. When the average thickness of the resin film 5 is less than the lower limit, the resin film 5 may have insufficient strength. When the average thickness of the resin film 5 exceeds the upper limit, the wiring substrate 2, and furthermore, the printed wiring board may have an unnecessarily large thickness.

### <Pre-Treated Surface>

The first pre-treated surface 5a and the second pre-treated surface 5b are formed by a surface treatment on a surface of the resin film 5 and contain oxygen atoms or nitrogen atoms.

The lower limit of the content ratio of oxygen atoms or nitrogen atoms of the first pre-treated surface 5a and the second pre-treated surface 5b is 0.2 atomic percent, preferably 1 atomic percent, and more preferably 5 atomic percent. The upper limit of the content ratio of oxygen atoms or nitrogen atoms of the first pre-treated surface 5a and the second pre-treated surface 5b is not particularly limited, but is, for example, 30 atomic percent. When the content ratio of oxygen atoms or nitrogen atoms of the first pre-treated surface 5a and the second pre-treated surface 5b is less than the lower limit, adhesiveness between the resin film 5 and the adhesive layer 4 and between the resin film 5 and the conductive pattern 6 may be insufficient.

The upper limit of the contact angle of the first pre-treated surface 5a and the second pre-treated surface 5b with respect to pure water is preferably 90°, and more preferably 80°. The lower limit of the contact angle of the first pre-treated surface 5a and the second pre-treated surface 5b with respect to pure water is not particularly limited. When the contact angle of the first pre-treated surface 5a with respect to pure water exceeds the upper limit, adhesive strength between the resin film 5 and the conductive pattern 6 may be insufficient. When the contact angle of the second pre-treated surface 5b with respect to pure water exceeds the upper limit, adhesive strength between the resin film 5 and the adhesive layer 4 may be insufficient.

The lower limit of a wetting tension of the first pre-treated surface 5a and the second pre-treated surface 5b is preferably 50 mN/m, and more preferably 60 mN/m. When the wetting tension of the first pre-treated surface 5a is less than the lower limit, an adhesive force between the resin film 5 and the conductive pattern 6 may be insufficient, and the conductive pattern 6 may be separated. When the wetting tension of the second pre-treated surface 5b is less than the lower limit, an adhesive force between the resin film 5 and the adhesive layer 4 may be insufficient, and the adhesive layer 4 may be separated.

The lower limit of the peel strength of an epoxy resin adhesive having an average thickness of 25 μm to the first pre-treated surface 5a and the second pre-treated surface 5b, the peel strength being measured using a polyimide sheet having an average thickness of 12.5 μm as a flexible adherend, is preferably 1 N/cm, and more preferably 5 N/cm. When the peel strength of the epoxy resin adhesive to the first pre-treated surface 5a or the second pre-treated surface 5b is less than the lower limit, the adhesive strength between the resin film 5 and the conductive pattern 6 or the adhesive strength between the resin film 5 and the adhesive layer 4 may be insufficient.

### (Conductive Pattern)

The conductive pattern 6 is formed of a conductive material laminated on the first pre-treated surface 5a of the resin film 5. This conductive pattern 6 has a desired planar shape that may include, for example, wiring portions that form electrical wiring and lands for mounting electronic components.

The conductive material that forms the conductive pattern 6 is not particularly limited. In general, a metal is used, and typically, copper is used as the conductive material.

The lower limit of the average thickness of the conductive pattern 6 is preferably 2 μm, and more preferably 5 μm. The upper limit of the average thickness of the conductive pattern 6 is not particularly limited, but is preferably 50 μm, and more preferably 30 μm. When the average thickness of the conductive pattern 6 is less than the lower limit, conductivity may be insufficient. When the average thickness of the conductive pattern 6 exceeds the upper limit, the wiring substrate 2, and furthermore, the printed wiring board may have an unnecessarily large thickness.

Note that the average thickness of the conductive pattern 6 is preferably larger than the upper limit in some cases, for example, in a case where a thin copper plate is patterned to form a conductive pattern 6, and the conductive pattern 6 is then bonded to the resin film 5.

An example of a method for forming the conductive pattern 6 is a method (so-called subtractive process) including preparing a substrate for a printed wiring board by laminating a conductive layer formed of the above conductive material on the first pre-treated surface 5a of the resin film 5, and patterning the conductive layer of the substrate for a printed wiring board by, for example, etching.

Note that the laminate in which the conductive layer is laminated on the first pre-treated surface 5a of the resin film 5, that is, the substrate for a printed wiring board, the substrate being prepared before the step of obtaining the wiring substrate 2 by forming the conductive pattern 6 by patterning, is also considered as an embodiment of the present invention.

The conductive layer of the substrate for a printed wiring board may be formed by depositing a metal directly on the first pre-treated surface 5a by, for example, vapor deposition or electroless plating or by laminating a sheet-like conductor such as a metal foil with an adhesive layer therebetween.

Examples of an adhesive that forms the adhesive layer include, but are not particularly limited to, various resin-based adhesives such as epoxy resins, polyimides, polyesters, phenolic resins, polyurethanes, acrylic resins, melamine resins, and polyamide-imides.

The lower limit of the average thickness of the adhesive layer is preferably 5 μm, and more preferably 10 μm. The upper limit of the average thickness of the adhesive layer is preferably 50 μm, and more preferably 40 μm. When the average thickness of the adhesive layer is less than the lower limit, the adhesive strength between the resin film 5 and the conductive layer may be insufficient. When the average thickness of the adhesive layer exceeds the upper limit, the substrate for a printed wiring board may have an unnecessarily large thickness.

The lower limit of the peel strength between the first pre-treated surface 5a and the conductive pattern 6 (conductive layer in the substrate for a printed wiring board) is preferably 1 N/cm, and more preferably 5 N/cm. When the peel strength between the first pre-treated surface 5a and the conductive pattern 6 is less than the lower limit, the conductive pattern 6 is easily separated by, for example, bending of the wiring substrate 2, and the wiring substrate 2, and furthermore, the printed wiring board may have insufficient reliability.

### [Method for Producing Printed Wiring Board]

Next, a method for producing the printed wiring board in FIG. 1 will be described.

The method for producing the printed wiring board includes a step of producing a coverlay 1, a step of producing a wiring substrate 2, and a step of laminating the coverlay 1 on a surface of the wiring substrate 2.

### <Coverlay Production Step>

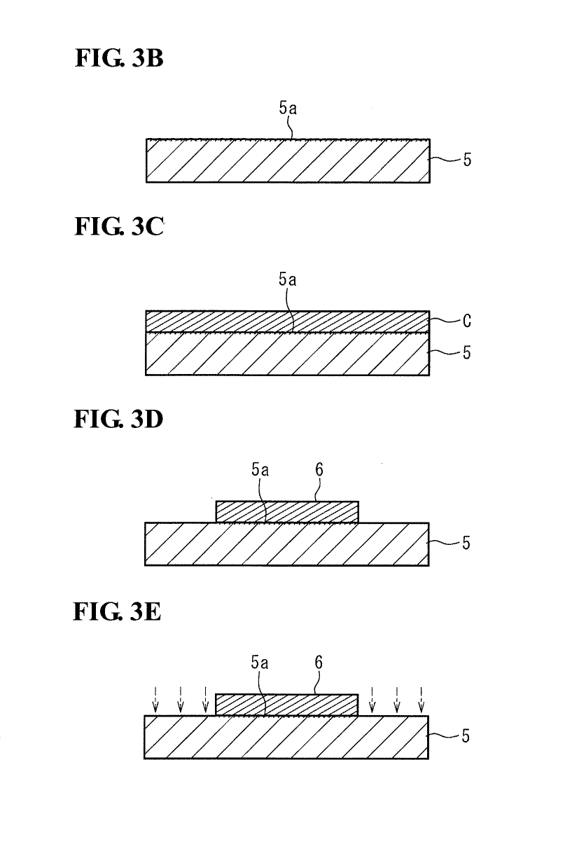

The step of producing a coverlay will be described with reference to FIGS. 2A to 2C.

The step of producing a coverlay includes a step of forming, on at least one surface of a resin film 3, a pre-treated surface 3a containing oxygen atoms or nitrogen atoms, and a step of laminating an adhesive layer 4 on the pre-treated surface 3a.

### (Pre-Treated Surface Formation Step)

In the step of forming a pre-treated surface, a surface treatment is performed on a resin film 3 as illustrated in FIG. 2A to form a pre-treated surface 3a as illustrated in FIG. 2B. In FIG. 2A, the surface treatment is schematically illustrated by the arrows. In FIGS. 2B and 2C, a region in which oxygen atoms or nitrogen atoms are introduced is schematically illustrated by the small point-like hatching. For the sake of ease of understanding, the drawings attached to the present application show so that the front surface side is located on the upper side. However, these illustrations do not limit the relationship in the vertical direction in the actual production steps.

Examples of the surface treatment capable of forming the pre-treated surface 3a containing oxygen atoms or nitrogen atoms include Na etching, an alkali treatment, a plasma treatment, and radiation exposure. In such a surface treatment, molecules of the outer surface of the resin film 3 are finely cut or removed (etched), and oxygen atoms or nitrogen atoms can be thereby added to the outer surface of the resin film 3.

The Na etching is a treatment in which a surface layer of a fluororesin of an outer surface of the resin film 3 is etched by immersing the resin film 3 in an etchant containing metallic Na, for example, “TETRA-ETCH” manufactured by Junkosha Inc. to add oxygen atoms or nitrogen atoms to the outer surface of the resin film 3.

The alkali treatment is a treatment in which a surface layer of a fluororesin of an outer surface of the resin film 3 is etched by immersing the resin film 3 in a liquid containing a strong alkali such as potassium hydroxide to add oxygen atoms or nitrogen atoms to the outer surface of the resin film 3.

The plasma treatment is a treatment in which an outer surface of a fluororesin of an outer surface of the resin film 3 is etched by bringing the resin film 3 into contact with plasma to add oxygen atoms or nitrogen atoms to the outer surface of the resin film 3. In an atmospheric-pressure plasma treatment, which is an example of this plasma treatment, plasma gas of oxygen, nitrogen, hydrogen, argon, ammonia, or the like is injected onto the back surface of the resin film 3. Alternatively, the entire outer surface of the laminate may be subjected to a plasma treatment by placing the resin film 3 in a plasma gas atmosphere. The plasma treatment may be performed by using plasma of an inert gas containing a compound having a hydrophilic group.

The radiation exposure is a treatment in which oxygen atoms or nitrogen atoms are added to the back surface of the resin film 3 in place of fluorine atoms by irradiating the back surface of the resin film 3 with high-energy radiation to extract fluorine atoms of a fluororesin on the back surface of the resin film 3. Examples of the radiation to be applied to the resin film 3 include electron beams and electromagnetic waves.

### (Adhesive Layer Lamination Step)

In the step of laminating an adhesive layer, an adhesive layer 4 is laminated on the pre-treated surface 3a of the resin film 3.

Consequently, the coverlay 1 is formed as illustrated in FIG. 2C.

The method for laminating the adhesive layer 4 is printing, coating, or the like and is appropriately selected in accordance with, for example, the thickness of the adhesive layer 4 and the material of the adhesive. Examples of the printing method that can be used include, but are not particularly limited to, screen printing, gravure printing, offset printing, flexographic printing, ink jet printing, and dispenser printing. Examples of the coating method that can be used include, but are not particularly limited to, knife coating, die coating, and roll coating.

### <Wiring Substrate Production Step>

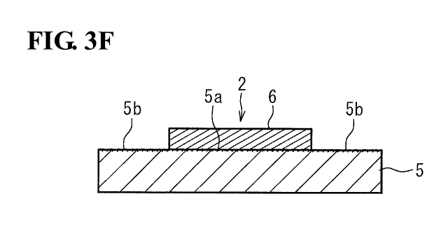

The step of producing a wiring substrate will be described with reference to FIGS. 3A to 3E.

The step of producing a wiring substrate includes a step of forming, on at least a front surface of a resin film 5, a first pre-treated surface 5a containing oxygen atoms or nitrogen atoms, a step of laminating a conductive layer C on the first pre-treated surface 5a, a step of forming a conductive pattern 6 by etching the conductive layer C, and a step of forming, in at least a conductive pattern-non-laminated region of the front surface of the resin film 5, a second pre-treated surface 5b containing oxygen atoms or nitrogen atoms.

### (First Pre-Treated Surface Formation Step)

In the step of forming the pre-treated surface, a surface treatment is performed on a resin film 5 as illustrated in FIG. 3A to form a first pre-treated surface 5a over the entire front surface of the resin film 5 as illustrated in FIG. 3B. In FIGS. 3A and 3E, the surface treatment is schematically illustrated by the arrows. In FIGS. 3B and 3E, a region containing oxygen atoms or nitrogen atoms is schematically illustrated by the fine hatching.

The method of the surface treatment for forming the first pre-treated surface 5a on the resin film 5 may be similar to the surface treatment for forming the pre-treated surface 3a on the resin film 3 in the step of forming a pre-treated surface of the step of producing the coverlay.

### (Conductive Layer Lamination Step)

In the step of laminating a conductive layer, as illustrated in FIG. 3C, a conductive layer C is laminated over the first pre-treated surface 5a of the resin film 5, the conductive layer C being obtained by forming a conductive material for forming a conductive pattern 6 into a layer or a sheet.

Examples of the method for laminating the conductive layer C include a method for depositing the conductive layer C on the first pre-treated surface 5a by plating and a method for bonding the conductive layer C to the first pre-treated surface 5a using an adhesive.

When the conductive layer C is deposited by plating, the conductive layer C can be formed by, for example, forming a thin underlying conductor layer on the first pre-treated surface 5a by, for example, electroless plating or application of conductive fine particles, and performing electroplating on the underlying conductor layer.

### (Conductive Pattern Formation Step)

In the step of forming a conductive pattern, the conductive layer C is selectively removed by a publicly known etching method including formation of a resist pattern to form the conductive pattern 6 as illustrated in FIG. 3D.

### (Second Pre-Treated Surface Formation Step)

In the step of forming the second pre-treated surface, as illustrated in FIG. 3E, a surface treatment the same as that in the step of forming the first pre-treated surface is again performed on the front surface of the resin film 5, the front surface having the conductive pattern 6 thereon, to form a second pre-treated surface 5b in a region where the conductive pattern 6 is not laminated, the region being disposed on the front surface of the resin film 5. Since the first pre-treated surface 5a in the conductive pattern-non-laminated region may also be removed during etching in the step of forming the conductive pattern, the second pre-treated surface 5b containing oxygen atoms or nitrogen atoms is formed again in this step.

### <Coverlay Lamination Step>

In the step of laminating a coverlay, the coverlay 1 produced in the step of producing a coverlay is laminated on the front surface of the wiring substrate 2 produced in the step of producing a wiring substrate. Thus, the printed wiring board in FIG. 1 is obtained.

### [Advantages]

The resin films 3 and 5 according to an embodiment of the present invention contain a fluororesin as a main component and thus have a low dielectric constant. The resin films 3 and 5 have, on at least one surface thereof, a pre-treated surfaces 3a, 5a, and 5b having a content ratio of oxygen atoms or nitrogen atoms of 0.2 atomic percent or more. Accordingly, hydrophobicity of the fluororesin is reduced by the oxygen atoms or nitrogen atoms to improve adhesiveness. Thus, the adhesive layer 4 or the conductive pattern 6 can be easily and reliably laminated. In particular, the pre-treated surfaces 3a and 5b enable the resin films 3 and 5 to be easily laminated with the adhesive layer 4 therebetween, that is, enable the coverlay 1 and the wiring substrate 2 to be easily and reliably laminated.

The coverlay 1 according to an embodiment of the present invention is obtained by laminating the adhesive layer 4 on the pre-treated surface 3a of the resin film 3, and thus the adhesive layer 4 is unlikely to separate from the resin film 3.

The printed wiring board according to an embodiment of the present invention is obtained by bonding the coverlay 1 laminated with the adhesive layer 4 to the pre-treated surface 3a of the conductive pattern 6. Accordingly, the peel strength between the pre-treated surface 3a and the adhesive layer 4 is high, and the resin film 3 is unlikely to separate.

The printed wiring board is obtained by laminating the conductive pattern 6 on the pre-treated surface 5a of the resin film 5. Accordingly, the conductive pattern 6 is unlikely to separate from the resin film 5.

According to the printed wiring board, since the resin film 5 has the pre-treated surface 5b in the conductive pattern-non-laminated region, the adhesive strength of the adhesive layer 4 of the coverlay 1 to the pre-treated surface 5b is high. Therefore, in the printed wiring board, the coverlay 1 can be easily laminated, and the laminated coverlay 1 is unlikely to separate.

### Other Embodiments

It is to be understood that the embodiments disclosed herein are only illustrative and are not restrictive in all respects. The scope of the present invention is not limited to the structures of the embodiments but is defined by the claims described below. It is intended that the scope of the present invention includes the meaning of equivalents of the claims and all modifications within the scope of the claims.

For example, the resin film may have, on both surfaces thereof, a pre-treated surface having a content ratio of oxygen atoms or nitrogen atoms of 1 atomic percent or more. In this case, it is easy and reliable to form a printed wiring board having a conductive pattern on both surfaces thereof and to laminate a reinforcing sheet or a shielding layer on the front surface of the coverlay.

In the printed wiring board, only one of the resin film serving as a base layer and the resin film of the coverlay may be the resin film containing a fluororesin as a main component and having the pre-treated surface.

A printed wiring board that does not include a coverlay is also included in the printed wiring board as long as the printed wiring board includes a base layer formed of a resin film having the pre-treated surface.

The formation of the pre-treated surface on the base layer is not essential as long as the printed wiring board includes a coverlay that includes a resin film having the pre-treated surface.

In the printed wiring board, the pre-treated surface may be formed in only one of the conductive pattern-laminated region and the conductive pattern-non-laminated region of the resin film that forms a base layer.

The pre-treated surface may be formed only on a part of a region of at least one surface of the resin film. The pre-treated surface may be formed only on a part of the conductive pattern-laminated region or the conductive pattern-non-laminated region of the base layer of the printed wiring board.

The printed wiring board may be a multilayer wiring board. Specifically, a multilayer printed wiring board having low dielectric loss, capable of being easily formed by lamination, and including layers that are unlikely to separate from each other can be provided by using base layers each formed of the resin film.

Even if a surface treatment is not performed after the formation of a conductive pattern, the printed wiring board is evaluated to have a pre-treated surface in the conductive pattern-non-laminated region as long as a pre-treated surface formed on a surface of a resin film before the lamination of a conductive layer is not lost in the step of forming the conductive pattern, that is, as long as the surface of the resin film exposed from the conductive pattern has a content ratio of oxygen atoms or nitrogen atoms of 0.2 atomic percent or more.

The resin film and the printed wiring board may include a modified layer that is formed on the pre-treated surface and that further improves adhesiveness. Examples of the modified layer include layers formed by applying a modifier such as a silane coupling agent or a titanium coupling agent.

The method for producing the printed wiring board is not limited to the production method described above. Modifications such as a change in the order of the steps, omission of any step, and addition of other publicly known steps may be made.

### Examples

The present invention will now be described in more details using Examples. However, the present invention is not interpreted in a limited manner on the basis of the description of the Examples.

In order to confirm advantages of the present invention, a surface treatment was performed using a plurality of plasma gases on surfaces of base films (average thickness: 25 μm) containing a tetrafluoroethylene-hexafluoropropylene copolymer (FEP) as a main component to prepare samples having different pre-treated surfaces. Note that films that did not substantially contain oxygen atoms or nitrogen atoms were used as the base films to be subjected to the surface treatment.

Oxygen, water vapor, argon, ammonia, or nitrogen was used as the plasma gas.

For each of the pre-treated surfaces of the samples and a surface that was not subjected to the surface treatment, the oxygen content ratio, the nitrogen content ratio, the contact angle of the surface with respect to pure water, a peel strength of an adhesive to the surface, and a peel strength of copper plating to the surface were measured. Table 1 shows the oxygen content ratios and the nitrogen content ratios of the pre-treated surfaces, evaluation results of an effect of reducing the pure-water contact angle due to the surface treatment, evaluation results of an effect of increasing adhesiveness to the adhesive due to the surface treatment, and evaluation results of an effect of increasing adhesiveness to the copper plating due to the surface treatment.

The “oxygen content ratio” and the “nitrogen content ratio” are values measured by X-ray photoelectron spectroscopy with an X-ray source of a K-alpha line of aluminum metal, with a beam diameter of 50 μm, and at an X-ray incident angle of 45° with respect to the analysis surface. Note that “<0.05%” in the table means that the content ratio was lower than 0.05%, which was the detection limit of the measuring apparatus, and could not be measured.

The “contact angle with respect to pure water” was measured in accordance with the sessile drop method in JIS-R-3257 (1999).

The “effect of reducing pure-water contact angle due to surface treatment” was evaluated as follows. When a reduction ratio of the contact angle of the pre-treated surface with respect to pure water relative to the contact angle of the surface of the untreated base film with respect to pure water was less than 1%, the result was denoted by “D”. When the reduction ratio was 1% or more and less than 10%, the result was denoted by “C”. When the reduction ratio was 10% or more and less than 20%, the result was denoted by “B”. When the reduction ratio was 20% or more, the result was denoted by “A”. The contact angle of the untreated surface with respect to pure water was 100°.

The “effect of increasing adhesiveness to adhesive due to surface treatment” was evaluated as follows. When a peel strength of the adhesive to the pre-treated surface was less than 1 N/cm, the result was denoted by “D”. When the peel strength was 1 N/cm or more and less than 3 N/cm, the result was denoted by “C”. When the peel strength was 3 N/cm or more and less than 5 N/cm, the result was denoted by “B”. When the peel strength was 5 N/cm or more, the result was denoted by “A”. The peel strength was measured by the method in accordance with JIS-K-6854-2 (1999) “Adhesives-Determination of peel strength of bonded assemblies-Part 2: 180° peel”. In the measurement of the peel strength, a coverlay in which a polyimide sheet (average thickness: 12.5 μm) and an epoxy adhesive (average thickness: 25 μm) were laminated was used. Among coverlays “CM-type” manufactured by Arisawa Manufacturing Co., Ltd., a coverlay including “Apical NPI” manufactured by Kaneka Corporation as a polyimide sheet was used as the coverlay. The peel strength of the adhesive to the untreated surface was 0.2 N/cm.

The “effect of increasing adhesiveness to copper plating due to surface treatment” was evaluated as follows. When a peel strength of copper plating to the pre-treated surface was less than 1 N/cm, the result was denoted by “D”. When the peel strength was 1 N/cm or more and less than 3 N/cm, the result was denoted by “C”. When the peel strength was 3 N/cm or more and less than 5 N/cm, the result was denoted by “B”. When the peel strength was 5 N/cm or more, the result was denoted by “A”. In copper plating, an underlying conductor layer was formed on the pre-treated surface by electroless plating, and electroplating was performed on the underlying conductor layer to form a copper plating layer having an average thickness of 12 μm. The peel strength was measured by the method in accordance with JIS-K-6854-2 (1999) “Adhesives-Determination of peel strength of bonded assemblies-Part 2: 180° peel”. In the measurement of the peel strength, a coverlay in which a polyimide sheet (average thickness: 12.5 μm) and an epoxy adhesive (average thickness: 25 μm) were laminated was used. Among coverlays “CM-type” manufactured by Arisawa Manufacturing Co., Ltd., a coverlay including “Apical NPI” manufactured by Kaneka Corporation as a polyimide sheet was used as the coverlay. The peel strength of the copper plating to the untreated surface was 0.1 N/cm.

TABLE 1

| | | | Effect of | Effect of | Effect of |
|---|---|---|---|---|---|
| | Oxygen | Nitrogen | reducing | increasing | increasing |
| | content ratio | content ratio | pure-water | adhesiveness | adhesiveness |
| | of pre-treated | of pre-treated | contact angle | to adhesive | to copper plating |
| Plasma | surface | surface | due to surface | due to surface | due to surface |
| gas | (atomic %) | (atomic %) | treatment | treatment | treatment |
| O₂ | 0.07% | <0.05% | D | D | D |
| | 0.4% | <0.05% | C | C | C |
| | 4.8% | <0.05% | B | B | B |
| | 6.0% | <0.05% | A | A | A |
| H₂O | 0.1% | <0.05% | D | D | D |
| | 0.2% | <0.05% | C | C | C |
| | 1.2% | <0.05% | B | B | B |
| | 5.5% | 0.5% | A | A | A |
| Ar | 0.16% | <0.05% | D | D | D |
| | 0.3% | <0.05% | C | C | C |
| | 1.7% | <0.05% | B | B | B |
| | 5.2% | 0.9% | A | A | A |
| NH₃ | <0.05% | 0.08% | D | D | D |
| | <0.05% | 0.2% | C | C | C |
| | <0.05% | 1.2% | B | B | B |
| | <0.05% | 5.5% | A | A | A |
| N₂ | <0.05% | 0.15% | D | D | D |
| | <0.05% | 0.3% | C | C | C |
| | <0.05% | 1.1% | B | B | B |
| | 0.2% | 5.8% | A | A | A |

These test results showed that the contact angle of a resin film with respect to pure water and adhesiveness of the resin film had a correlation to the content ratio of oxygen atoms or nitrogen atoms of the pre-treated surface. It was confirmed that the formation of a pre-treated surface having a content ratio of oxygen atoms or nitrogen atoms of 0.2 atomic percent or more can sufficiently reduce the contact angle with respect to pure water and sufficiently improve adhesiveness.

As described above, it was confirmed that other materials could be easily laminated on a resin film having a pre-treated surface according to the present invention, and the other materials were unlikely to separate.

### INDUSTRIAL APPLICABILITY

The present invention is widely applicable to a resin film containing a fluororesin as a main component, the resin film being laminated with another layer in a printed wiring board or the like.

### REFERENCE SIGNS LIST

1 coverlay, 2 wiring substrate, 3 resin film, 3a pre-treated surface 4 adhesive layer, 5 resin film (base layer), 5a pre-treated surface 5b pre-treated surface, 6 conductive pattern, C conductive layer

1: A resin film comprising a fluororesin as a main component,
wherein the resin film has, on at least one surface thereof, a pre-treated surface having a content ratio of oxygen atoms or nitrogen atoms of 0.2 atomic percent or more.

2: The resin film according to claim 1, wherein a contact angle of the pre-treated surface with respect to pure water is 90° or less.

3: The resin film according to claim 1, wherein a peel strength of an epoxy resin adhesive having an average thickness of 25 μm to the pre-treated surface, the peel strength being measured using a polyimide sheet having an average thickness of 12.5 μm as a flexible adherend, is 1 N/cm or more.

4: A coverlay for a printed wiring board, the coverlay comprising the resin film according to claim 1; and an adhesive layer laminated on the pre-treated surface.

5: The coverlay for a printed wiring board according to claim 4, wherein a peel strength between the adhesive layer and the pre-treated surface is 1 N/cm or more.

6: A substrate for a printed wiring board, the substrate comprising the resin film according to claim 1; and a conductive layer laminated on the pre-treated surface.

7: The substrate for a printed wiring board according to claim 6, wherein a peel strength between the pre-treated surface and the conductive layer is 1 N/cm or more.

8: A printed wiring board comprising:
an insulating base layer;
a conductive pattern laminated on at least one surface of the base layer; and
the coverlay for a printed wiring board according to claim 4, the coverlay being laminated on the conductive pattern.

9: A printed wiring board comprising the resin film according to claim 1; and a conductive pattern laminated on the pre-treated surface.

10: A printed wiring board comprising the resin film according to claim 1; and a conductive pattern laminated on a surface of the resin film,
wherein the pre-treated surface is disposed in a conductive pattern-non-laminated region on the surface of the resin film.

11: The printed wiring board according to claim 10, wherein the pre-treated surface is disposed in a conductive pattern-laminated region.
